(19) United States
(12) Patent Application Publication
(10) Pub. No.: US 2025/0283642 A1
(43) Pub. Date: Sep. 11, 2025

(54) SELECTIVE ABSORPTION FILTERS FOR OIL-BASED IMMERSION COOLING

(71) Applicant: SEAGATE TECHNOLOGY LLC, Fremont, CA (US)

(72) Inventors: Li Hong Zhang, Shugart (SG); Michael Yi Zhao Yao, Shugart (SG); Swee Chuan Gan, Shugart (SG); Akhil Namboori, Shugart (SG); Xiong Liu, Shugart (SG); Brendon Shi Wei Leong, Shugart (SG)

(21) Appl. No.: 18/600,962

(22) Filed: Mar. 11, 2024

(51) Int. Cl. F25B 43/00; B01D 17/02; H05K 7/20

(52) U.S. Cl. CPC F25B 43/003; B01D 17/0202; H05K 7/20236; B01D 2253/1085; B01D 2253/31; B01D 2257/30; B01D 2257/70; B01D 2257/80

(57) ABSTRACT

Described are adsorption filters for filtering hydrocarbon cooling oils. The adsorption filters include a molecular sieve composite mixture that combines at least two filter materials that each have a surface chemistry and/or a pore size distribution that is selected to target the preferential adsorption of contaminants present or expected to be present in the hydrocarbon cooling oils, for example from oxidation of the oils, from electronic components immersed in the oils for cooling, or from other environmental factors. At least one of the filter materials may be an alkali metal aluminosilicate molecular sieve.

The disclosure generally relates to oil-based immersion cooling of electronic components.

### SUMMARY

Techniques and systems of the present disclosure relate to materials and methods to improve the reliability and serviceability of immersion cooling systems using hydrocarbon oil coolants and to extend the useful life of the electronic components being cooled.

In accordance with certain aspects, the present disclosure provides adsorption filters for filtering hydrocarbon cooling oils, the adsorption filters including a molecular sieve composite mixture that includes at least a first filter material and a second filter material. The first filter material has a surface chemistry and/or a pore size distribution selected for preferential adsorption of a first contaminant present or expected to be present in the hydrocarbon cooling oil, and the second filter material has a surface chemistry and/or a pore size distribution selected for preferential adsorption of a second contaminant present or expected to be present in the hydrocarbon cooling oil. In certain aspects, the first material comprises an alkali metal aluminosilicate molecular sieve.

In certain aspects, the first contaminant may be a polar chemical resulting from oxidation of the hydrocarbon cooling oil, for example a carboxylic acid.

In certain aspects, the first or second contaminant is water, a sulfur compound, a hydroxylate, a ketone, or an aldehyde.

In certain aspects, the second filter material is a molecular sieve, a clay, or a silica gel.

In certain aspects, the first filter material and the second filter material have different pore size distributions.

In certain aspects, the pore size distribution of the first filter material is in the nanopore range and the pore size distribution of the second filter material is in the micropore, mesopore, or macropore range.

In certain aspects, one or both of the first filter material and the second filter material has an alkaline-modified surface chemistry, for example due to exposure to sodium hydroxide, potassium hydroxide, sodium carbonate, or potassium carbonate.

In certain aspects, the first filter material has a silicon to aluminum ratio of about 4 to 1 or less.

In certain aspects, the first filter material has a silicon to aluminum ratio of about 4 to 1 or more.

In certain aspects, one of the first filter material and the second filter material is selected to target absorption of water, and the other of the first filter material and the second filter material is selected to target absorption of polar chemicals.

In certain aspects, the adsorption filter includes a third filter material, and

wherein a first one of the first, second, and third filter materials is selected to target absorption of water, a second one of the first, second, and third filter materials is selected to target absorption of polar chemicals, and a third one of the first, second, and third filter materials is selected to target absorption of non-polar chemicals.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic depiction of an example oil-based immersion cooling system.

FIG. 2 is a schematic representation of an example of a selective adsorption filter in accordance with aspects of the present disclosure.

FIGS. 3A and 3B are diagrams of chemisorption of carboxylic acids onto materials useful as molecular sieves in accordance with aspects of the present disclosure.

FIG. 4 is a flow chart of steps that may be performed in accordance with aspects of the present disclosure.

### DETAILED DESCRIPTION

The present disclosure relates to tuning the selectivity of selective absorbent compositions to target the contaminants present in oil-based coolants, and particularly to polar chemicals resulting from the oxidation of oil-based coolants used to cool electronic components such as processors and data storage devices. This can lead to extending the field life of the electronic components and of the cooling system, as well as to reducing the overall operation cost for cooling. Hydrocarbon oils of the type used in immersion cooling are readily oxidized to form polar chemicals, thereby increasing the dielectric constant and corrosivity of the coolant oils, both of which will adversely affect electronic components over time. In accordance with the present disclosure, using absorbents such as molecular sieves, clays, and silica gels having pore sizes ranging from nanopores to mesopores to macropores, various oxidization compounds and polar compounds in the cooling oil can be effectively absorbed. Moreover, these absorbents can be modified with alkaline chemicals to increase their absorption selectivity, allowing composite adsorbent mixtures to be fashioned that combine different adsorption selectivities, each of which being tuned to removal of one or more contaminants present in the oil.

Oil-based immersion cooling normally uses hydrocarbon oils as the cooling liquid, for example mineral oils, synthetic oils, or biological oils. Hydrocarbon oils degrade over time due to oxidation, and such oxidation may be accelerated by heat and the presence of water or certain other chemicals. In applications where the cooled electronic devices can generate excessive amounts of heat (such as with CPUs and GPUs, as well as with data center storage devices like SSDs and hard drives), oxidation of the cooling oils is an unavoidable problem. Oxidation of hydrocarbon oils mainly forms degraded carboxylic acids, and can also form other oxidation products that include hydroxylates, ketones, and aldehydes. Carboxylic acid contamination can also arise from the dissolution of some PCBA materials found in circuit boards of electronic components.

Because oxidization products often have higher polarity compared to the base oil, their presence will increase the dielectric constant, viscosity, acidity, and corrosiveness of the base oils, often resulting in one or more of the following problems: reduced cooling efficiency due to an increase in viscosity; increased cost from more frequent need to change the coolant; degraded signal-to-noise ratios of the electronic devices due to the degraded dielectric properties of the oils; and corroded equipment. Liquid cooling tanks often employ filtration to remove particles or contaminants, with active carbon filters being the most common. However, the activated carbon particles in such filters can be released into the hydrocarbon oils, thus potentially further degrading the dielectric properties of the oils.

In accordance with various aspects of the present disclosure, alkali metal aluminosilicates are used as molecular sieve filters to remove contaminants (carboxylic acids, water, sulfur compounds, and so forth) from cooling oil. The molecular sieve filters are composite mixtures of molecular sieve materials having different surface chemistry selectivities (that is, surface chemical affinities) and/or pore size distributions that are tuned to the contamination found or expected to be found based on the type of oil used and the environmental conditions such as temperature and presence of water. By using composite mixtures having different selectivities, multiple contaminants can be targeted simultaneously. Some benefits may include: maintaining the physical and electrical properties of the hydrocarbon oil coolants by selectively absorbing the oxidized products; improving reliability of the electronic components by retaining the electrical integrity, especially the dielectric constant, of the cooling oils (particularly benefiting high-frequency signal transmission by preventing insertion loss degradation); improving the reliability and serviceability of the cooling systems by consistently removing corrosive chemicals, which are mostly polar; maintaining the viscosity of the cooling oils by removing the harmful polar chemicals, which helps the cooling power efficiency; and reducing cost by increasing the service life of the cooling oils.

Reference will now be made to the drawings, which depict one or more aspects described in this disclosure. However, it will be understood that other aspects not depicted in the drawings fall within the scope of this disclosure. Like numbers used in the figures refer to like components, steps, and the like. However, it will be understood that the use of a reference character to refer to an element in a given figure is not intended to limit the element in another figure labeled with the same reference character. In addition, the use of different reference characters to refer to elements in different figures is not intended to indicate that the differently referenced elements cannot be the same or similar.

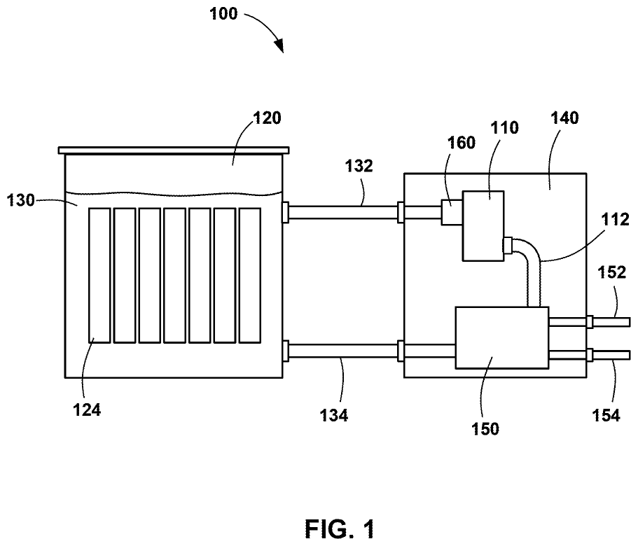

FIG. 1 schematically shows an example configuration for an oil immersion cooling system 100, such as for use in a data center. Immersion tank 120 includes electronic components 124 immersed in a cooling liquid 130. The electronic components 124 may include components such as servers, processors, storage devices, and the like. The cooling liquid 130 is an oil such as, for example, a hydrocarbon oil, whether a mineral oil, synthetic oil, or biological oil. Oils that have been successfully used to cool computer servers and data centers include transformer oils and other electrical cooling oils, and can even include non-purpose oils such as cooking oils, motor oils, and silicone oils.

A pumping unit 140 is connected to the immersion tank 120 via inlet pipe 132 and outlet pipe 134. While the pumping unit 140 is shown separated from the immersion tank 120, it can also be integrated into the immersion tank. The pumping unit 140 includes a pump 160, a filtration unit 110, and a heat exchanger 150. Upon receiving heated oil from the immersion tank 120 via inlet pipe 132, pumping unit 140 filters the oil using filtration unit 110. Filtration unit 110 includes selective adsorption filters in accordance with the present disclosure. Oil cleaned by filtration unit 110 is directed by pipe 112 to a heat exchanger 150, which may use air or water from a cooling tower (not shown) that is cycled through pipes 152 and 154 to thereby cool the oil for recirculation into the immersion tank 120 via outlet pipe 134. The particular arrangement of pump 160, filtration unit 110, pipe 112, and heat exchanger 150 as shown in FIG. 1 is illustrative only, and any suitable arrangement may be used. Moreover, heat exchanger 150 can be any suitable heat exchange device that functions on any principle compatible with the immersion cooling application, the cooling oil, the filtration arrangement, and so forth.

Cooling system 100 may include devices to aid in the determination of contaminants present in the oil, as well as to monitor the temperature of the oil. Information from such sensors and devices can be used to determine the composition of the selective absorption filter in filtration unit 110. In addition, the filtration unit 110 can monitor the filter use and efficacy to determine when the filter requires regeneration or replacement. Regeneration of the filter may be accomplished by baking the filter to sufficient temperatures to remove the organic residues and other captured contaminants, or by a process of calcination (or re-calcination) as desired or appropriate for the type of filter material used. In addition, molecular sieves can be regenerated by other methods including vacuum regeneration (involving placing the molecular sieve material in a high vacuum environment to remove the adsorbed chemicals by degassing, with or without the application of heat), pressure swing adsorption (alternating between high pressure to adsorb molecules and low pressure to desorb them), and liquid desorption (immersing the molecular sieve in a desorbing liquid that displaces the adsorbed molecules).

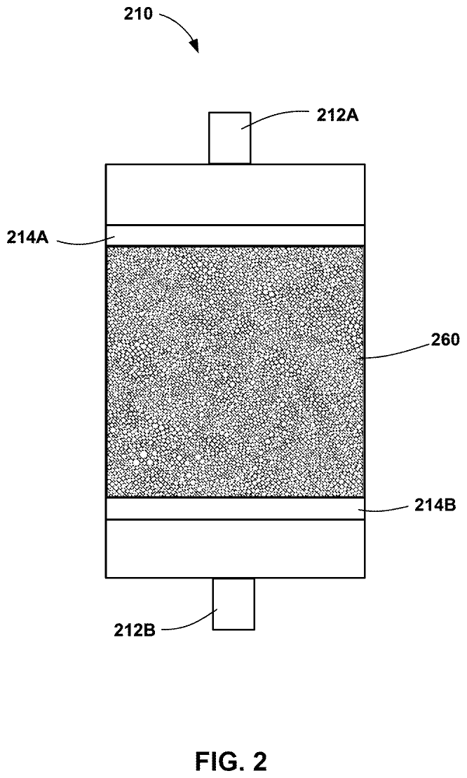

FIG. 2 schematically shows one particular example of a filter configuration 210 that includes an inlet 212A, an optional inlet mesh filter 214 A, a molecular sieve composite 260, an optional outlet mesh filter 214B, and an outlet 212B. The molecular sieve composite includes a mixture of at least two selective adsorption filter materials, one being an alkali metal aluminosilicate molecular sieve material, and the other being at least one of the following: another alkali metal aluminosilicate molecular sieve material, a different molecular sieve material, a clay material, or a silica gel material. Each of the selective adsorption materials has a pore size and/or a surface chemistry affinity tuned for adsorption of one or more targeted contaminants. The molecular sieve composite may be provided in any suitable manner, including as particulates in a porous container or trapped between porous barriers, as particulates dispersed in a membrane or webbing that can be layered, folded, rolled, or disposed in any other suitable fashion in a filtration unit.

Without wishing to be bound to any theory, it is useful to understand that carboxylic acids and other oxidation products of the hydrocarbon oils have a higher polarity and thus can form affinity with the absorbent materials through electrostatic forces in addition to physical (van der Walls) forces. Absorbent materials that have absorption selectivity to higher polarity oxidation products include aluminosilicate molecular sieves, clays, and silica gels. In accordance with the present disclosure, these materials can be chosen for their absorption selectivity to particular contaminants, they can be modified to increase their absorption selectivity, and they can be mixed with other absorbents to form a composite tuned to selectively adsorb multiple types of contaminants, for example carboxylic acids, sulfur compounds, and water.

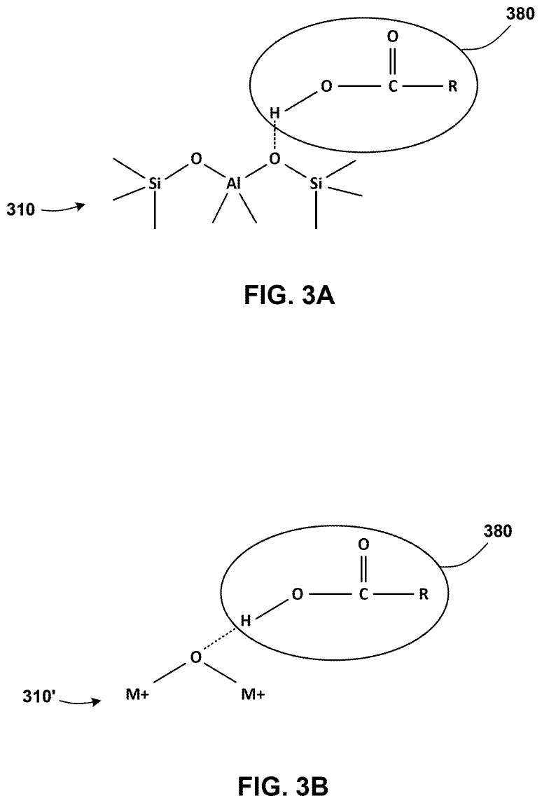

In accordance with the present disclosure, molecular sieves may be used as the adsorbent materials to selectively absorb carboxylic acids and other oxidized products of hydrocarbon oil coolants. Molecular sieves are alkali metal aluminosilicates having adsorptive properties that originate from the electronegative atoms on the surface, which are available to form hydrogen bonds with the oxidized hydrocarbons, as shown in FIG. 3A where carboxylic compound 380 is captured at an oxygen site on molecular sieve surface 310.

Molecular sieves are often characterized into classes based on pore size, namely nanoporous or microporous (2 nm pore size or less), mesoporous (2 nm to 50 nm pore size), and macroporous (50 nm pore size or greater). To target certain or multiple different contaminants, molecular sieve filters can be fashioned from combinations of different pore sizes. Moreover, the pore sizes and surface chemistry (that is, the degree of hydrophobicity or hydrophilicity) of the molecular sieves will depend on the silicon to aluminum ratio (Si/Al). Low Si/Al ratio (lower than about 4:1) generally means higher hydrophilicity of the surfaces, resulting in molecular sieves that are more selective to the absorption of polar chemicals, including water.

To further enhance the chemical selectivity of molecular sieve adsorption towards the oxidized products of hydrocarbon oils, the molecular sieves can be modified by exposure to alkaline chemicals such as sodium hydroxide (NaOH) or potassium hydroxide (KOH), sodium carbonate (Na₂CO₃), or potassium carbonate (K₂CO₃). The modification process may involve soaking the molecular sieve materials in an aqueous solution of the modifying agent, followed by calcination at high temperatures, for example 400 degrees C. or higher. Such a process will result in the formation of strong basic sites inside the molecular sieve cages. The basic sites may include alkali oxides such as CaO, K₂O, and Na₂O, depending on the modifying agent used. As indicated in FIG. 3B, the basic sites M+ on the surface of a modified molecular sieve 310′ can readily bond with carboxylic acid 380 through electrostatic forces.

As already noted in the present disclosure, there may be contaminants other than the oxidized products of the hydrocarbon oils that need to be adsorbed, for example water and/or sulfur compounds. When taking into account the adsorption of multiple different contaminants, molecular sieve composite mixtures may be formulated so that they contain different chemical selectivity and size selectivity to target absorption of the different contaminants. Examples of composite mixtures include the following: (A) a 2-in-1 molecular sieve composite mixture including 1 part selected to target absorption of water and 1 part to target absorption of polar chemicals such as the oxidized products of the hydrocarbon oils; (B) a 3-in-1 molecular sieve composite mixture including 1 part to absorb water, 1 part to absorb oxidized compounds of hydrocarbon oils, and 1 part to target adsorption of non-polar contaminants; and (C) a 4-in-1 molecular sieve composite mixture including 1 part to adsorb water, 1 part is to absorb the oxidized compounds of hydrocarbon oils, 1 part to absorb non-polar contaminants, and 1 part mesoporous molecular sieve material to adsorb large organic contaminants.

For targeting water absorption, 3A type and 4A type zeolite molecular sieves can be used. For targeting polar chemical adsorption, low Si/Al ratio (less than about 4:1) molecular sieves, Beta-type molecular sieves, and the alkaline-modified molecular sieves can be used. For targeting non-polar chemical adsorption, high Si/Al ratio (greater than about 4:1) molecular sieves can be used. Silica gels can also be used as an adsorbent alone or together with the molecular sieves. Silica gels typically have larger pores that fall into the mesoporous or microporous categories, and so may be used to absorb large organic compounds. Silica gels can also be alkaline modified to enhance adsorption selectivity to the oxidized products within the hydrocarbon oils. A non-exhaustive and non-limiting list of example materials, pore sizes, and adsorption selectivity is set forth in Table 1.

TABLE 1

| | | | Preferred Adsorption |
|---|---|---|---|
| Material | Pore Size | | Selectivity |
| 3A Zeolite | 0.3 | nm | water |
| Molecular Sieve | | | |
| 4A Zeolite | 0.4 | nm | water |
| Molecular Sieve | | | |
| 10A or 13X Zeolite | about 1 nm | | small and medium organics |
| Molecular Sieve | | | |
| Y Type Zeolite | 0.74 | nm | small and medium organics |
| Molecular Sieve | | | |
| Beta Type Zeolite | 0.7 | nm | small and medium organics |
| Molecular Sieve | | | |

| | | |
|---|---|---|
| MCM-41 | mesoporous | small to large organics |
| Silica Gel | meso or macro | small to large organics |
| High Si/Al ratio | nanoporous | non-polar compounds |
| Low Si/Al ratio | nanoporous | polar compounds, water |
| Surface Modified | various | various |

In determining what adsorbents to utilize in molecular sieve composite filters in accordance with the present disclosure, and especially in determining effective pore sizes, it may be useful to take into account the kinetic diameter of the targeted contaminants. Kinetic diameter as applied to molecules is a measure that expresses the likelihood that the molecule will collide with another molecule, and is an indication of the effective size, or bulk, of the molecule in a dynamic environment. As such, molecular sieve pore size should be selected to be on the order of, or slightly larger than, the kinetic diameter of the target contaminant molecules. For purposes of illustration and comparison, Table 2 sets forth known kinetic diameters of various example molecules.

TABLE 2

| | Kinetic Diameter |
|---|---|
| Molecule | (nm) |
| Water | 0.265 |
| Methane | 0.380 |
| Acetylene | 0.330 |
| Ethylene | 0.390 |
| Hydrogen Sulfide | 0.360 |
| Cyclohexane | 0.480 |
| Dimethylbutane | 0.560 |

In practice, the products of hydrocarbon cooling oil oxidation will often include various types of organic contaminants, mainly polar organics such as alcohols, aldehydes and organic acids. The estimated kinetic diameters of most such oxidation products are in the range of 0.5 to 1.0 nm, although some may have kinetic diameters greater than 1.0 nm, including in the mesopore range.

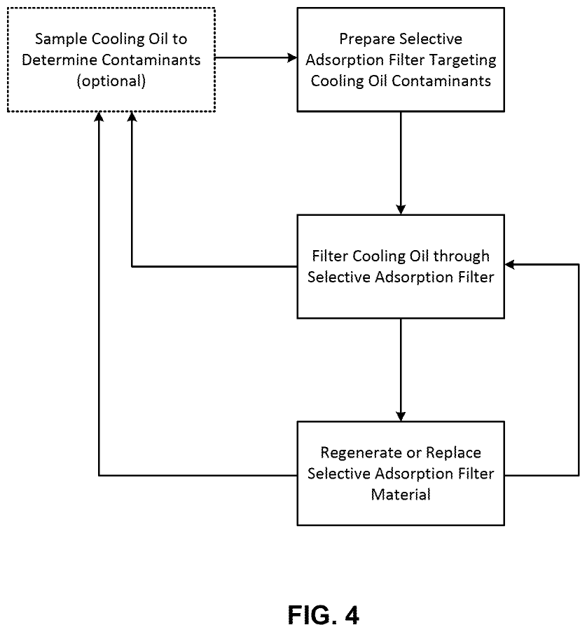

FIG. 4 shows a flow chart depicting steps for filtering cooling oil using selective adsorption filters that include molecular sieve composites in accordance with the present disclosure. The selective adsorption filter may be prepared to target contaminants in the cooling oil, whether those contaminants are expected (for example based on the composition of the oil, environmental factors such as temperature, the presence of other materials, and so forth) or measured through optional sampling (including in situ sensing) of the cooling oil. Upon preparation, the filter can be installed and used to filter the cooling oil. Periodically, the filter can be replaced and/or regenerated (either off-line or in situ) when the filter loses sufficient efficacy due to the amount of absorbed contaminants. At the occasion of replacing or regenerating the filter, the composition and mixtures of the filter materials may be re-evaluated.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this disclosure are described as being performed by a single module or unit for purposes of clarity, it should be understood that the techniques of this disclosure may be performed by a combination of units or modules.

In one or more examples, the described techniques may be implemented in hardware, software, firmware, or any combination thereof. If implemented in software, the functions may be stored as one or more instructions or code on a computer-readable medium and executed by a hardware-based processing unit. Computer-readable media may include non-transitory computer-readable media, which corresponds to a tangible medium such as data storage media.

As used herein, the term “configured to” may be used interchangeably with the terms “adapted to” or “structured to” unless the content of this disclosure clearly dictates otherwise.

As used herein, the term “or” refers to an inclusive definition, for example, to mean “and/or” unless its context of usage clearly dictates otherwise. The term “and/or” refers to one or all of the listed elements or a combination of at least two of the listed elements.

As used herein, the phrases “at least one of” and “one or more of” followed by a list of elements refers to one or more of any of the elements listed or any combination of one or more of the elements listed.

As used herein, the terms “coupled” or “connected” refer to at least two elements being attached to each other either directly or indirectly. An indirect coupling may include one or more other elements between the at least two elements being attached. Further, in one or more embodiments, one element “on” another element may be directly or indirectly on and may include intermediate components or layers therebetween. Either term may be modified by “operatively” and “operably,” which may be used interchangeably, to describe that the coupling or connection is configured to allow the components to interact to carry out described or otherwise known functionality. For example, a controller may be operably coupled to a resistive heating element to allow the controller to provide an electrical current to the heating element.

As used herein, any term related to position or orientation, such as “proximal,” “distal,” “end,” “outer,” “inner,” and the like, refers to a relative position and does not limit the absolute orientation of an embodiment unless its context of usage clearly dictates otherwise.

All scientific and technical terms used herein have meanings commonly used in the art unless otherwise specified. The definitions provided herein are to facilitate understanding of certain terms used frequently herein and are not meant to limit the scope of the present disclosure.

The singular forms “a,” “an,” and “the” encompass embodiments having plural referents unless its context clearly dictates otherwise.

As used herein, “have,” “having,” “include,” “including,” “comprise,” “comprising” or the like are used in their open-ended sense, and generally mean “including, but not limited to.” It will be understood that “consisting essentially of,” “consisting of,” and the like are subsumed in “comprising,” and the like.

Reference to “one embodiment,” “an embodiment,” “certain embodiments,” or “some embodiments,” etc., means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the disclosure.

What is claimed is:

1. An adsorption filter for filtering a hydrocarbon cooling oil, the adsorption filter including a molecular sieve composite mixture that comprises:
a first filter material comprising an alkali metal aluminosilicate molecular sieve and having a surface chemistry and/or a pore size distribution selected for preferential adsorption of a first contaminant present or expected to be present in the hydrocarbon cooling oil; and
a second filter material having a surface chemistry and/or a pore size distribution selected for preferential adsorption of a second contaminant present or expected to be present in the hydrocarbon cooling oil.

2. The adsorption filter of claim 1, wherein the first contaminant is a polar chemical resulting from oxidation of the hydrocarbon cooling oil.

3. The adsorption filter of claim 1, wherein the first contaminant is a carboxylic acid.

4. The adsorption filter of claim 1, wherein the first contaminant or second contaminant is water.

5. The adsorption filter of claim 1, wherein the first contaminant or second contaminant is a sulfur compound.

6. The adsorption filter of claim 1, wherein the first contaminant or second contaminant a hydroxylate, a ketone, or an aldehyde.

7. The adsorption filter of claim 1, wherein the second filter material is a molecular sieve, a clay, or a silica gel.

8. The adsorption filter of claim 1, wherein the first filter material and the second filter material have different pore size distributions.

9. The adsorption filter of claim 1, wherein the pore size distribution of the first filter material is in the nanopore range and the pore size distribution of the second filter material is in the micropore, mesopore, or macropore range.

10. The adsorption filter of claim 1, wherein one or both of the first filter material and the second filter material has an alkaline-modified surface chemistry.

11. The adsorption filter of claim 10, wherein the alkaline-modified surface chemistry is due to exposure to sodium hydroxide, potassium hydroxide, sodium carbonate, or potassium carbonate.

12. The adsorption filter of claim 1, wherein the first filter material has a silicon to aluminum ratio of about 4 to 1 or less.

13. The adsorption filter of claim 1, wherein the first filter material has a silicon to aluminum ratio of about 4 to 1 or more.

14. The adsorption filter of claim 1, wherein one of the first filter material and the second filter material is selected to target absorption of water, and the other of the first filter material and the second filter material is selected to target absorption of polar chemicals.

15. The adsorption filter of claim 1, further comprising a third filter material, and wherein a first one of the first, second, and third filter materials is selected to target absorption of water, a second one of the first, second, and third filter materials is selected to target absorption of polar chemicals, and a third one of the first, second, and third filter materials is selected to target absorption of non-polar chemicals.

16. The adsorption filter of claim 15, wherein each of the first, second, and third filter materials has either a microporous or a mesoporous pore size distribution, and further comprising a fourth filter material having a mesoporous pore distribution to absorb large organic contaminants.

17. The adsorption filter of claim 16, wherein the fourth filter material is a molecular sieve or a silica gel.

18. An oil immersion cooling system for using the hydrocarbon cooling oil to cool one or more electronic components, and comprising the adsorption filter of claim 1.

19. The oil immersion cooling system of claim 18, wherein the electronic components are processing devices.

20. The oil immersion cooling system of claim 18, wherein the electronic components are data storage devices.
